(19) United States
(12) Patent Application Publication
(10) Pub. No.: US 2025/0151327 A1
(43) Pub. Date: May 8, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Yoonhee KANG, Suwon-si (KR); Junchae LEE, Suwon-si (KR); Sungsoo KIM, Suwon-si (KR); Kyuhee HAN, Suwon-si (KR)

(73) Assignee: Samsung Electronics Co., Ltd., Suwon-si (KR)

(21) Appl. No.: 18/666,927

(22) Filed: May 17, 2024

(30) Foreign Application Priority Data
Nov. 3, 2023 (KR) 10-2023-0151003

(51) Int. Cl. H01L 29/423; H01L 29/06; H01L 29/417; H01L 29/775; H01L 29/786

(52) U.S. Cl. CPC H10D 30/6735; H10D 30/43; H10D 30/6729; H10D 30/6757; H10D 62/121; H10D 64/258

(57) ABSTRACT

A semiconductor device includes a substrate; an active pattern extending on the substrate in a first direction; a plurality of channel layers on the active pattern; a gate structure surrounding the plurality of channel layers, and extending in a second direction that intersects the first direction; blocking insulating layers on both side surfaces of the gate structure, respectively, each of the blocking insulating layers having an upper region having a first thickness and a lower region having a second thickness smaller than the first thickness; source/drain patterns on portions of the active pattern on both sides of the gate structure, the source/drain patterns defining trenches therein; contact structures on the source/drain patterns and filling the trenches; and a metal-semiconductor compound layer between the source/drain patterns and the contact structures.

### CROSS-REFERENCE TO RELATED APPLICATION(S)

This application claims benefit of priority to Korean Patent Application No. 10-2023-0151003 filed on Nov. 3, 2023 in the Korean Intellectual Property Office, the disclosure of which is incorporated herein by reference in its entirety.

### BACKGROUND

The present disclosure relates to semiconductor devices and methods of manufacturing the same.

As demand for high performance, high speed, and/or multifunctionality of semiconductor devices has increased, demand for integration density of semiconductor devices has increased. To meet the demand for high integration of semiconductor devices, the development of semiconductor devices including channels in a three-dimensional structure has been actively advanced.

### SUMMARY

Some example embodiments provide a semiconductor device having improved electrical properties and reliability.

Some example embodiments provide a method of manufacturing a semiconductor device having improved electrical properties and reliability.

Some example embodiments of the inventive concepts provide a semiconductor device that includes a substrate; an active pattern extending on the substrate in a first direction; a plurality of channel layers stacked on the active pattern, the plurality of channel layers being spaced apart from each other in a direction perpendicular to an upper surface of the substrate; a gate structure crossing the active pattern, the gate structure surrounding the plurality of channel layers and extending in a second direction that intersects the first direction; blocking insulating layers on both side surfaces of the gate structure, respectively, each of the blocking insulating layers having an upper region having a first thickness and a lower region having a second thickness smaller than the first thickness; source/drain patterns on portions of the active pattern on both sides of the gate structure, the source/drain patterns connecting side surfaces of the plurality of channel layers, and the source/drain patterns defining trenches therein, respectively; contact structures on the source/drain patterns between the blocking insulating layers, the contact structures filling the trenches; and a metal-semiconductor compound layer between the source/drain patterns and the contact structures.

Some example embodiments of the inventive concepts further provide a semiconductor device that includes a substrate; an active pattern extending on the substrate in a first direction; a plurality of channel layers stacked on the active pattern, the plurality of channel layers being spaced apart from each other in a direction perpendicular to an upper surface of the substrate; a gate structure including a gate electrode crossing the active pattern, the gate electrode surrounding the plurality of channel layers and extending in a second direction that intersects the first direction, gate spacers on both side surfaces of the gate electrode, respectively, and a gate capping layer on the gate electrode and the gate spacers, the gate capping layer having a material different from a material of the gate spacers; source/drain patterns along side surfaces of the plurality of channel layers, the source/drain patterns being on portions of the active pattern on both sides of the gate structure, and the source/drain patterns defining trenches therein, respectively; blocking insulating layers including first portions on both side surfaces of the gate capping layer, respectively, and second portions extending from the first portions to side surfaces of the gate spacers, respectively, and each of the second portions having a thickness smaller than a thickness of each of the first portions; and contact structures on the source/drain patterns between the blocking insulating layers, the contact structures filling the trenches.

Some example embodiments of the inventive concepts still further provide a semiconductor device that includes a substrate; an active pattern extending on the substrate in a first direction; a device isolation layer on the substrate and defining the active pattern; a plurality of channel layers stacked on the active pattern, the plurality of channel layers being spaced apart from each other in a direction perpendicular to an upper surface of the substrate; a gate structure crossing the active pattern, the gate structure surrounding the plurality of channel layers and extending in a second direction that intersects the first direction; blocking insulating layers on both side surfaces of the gate structure, respectively, and each of the blocking insulating layers having an upper region having a first thickness and a lower region having a second thickness smaller than the first thickness; source/drain patterns including a first epitaxial layer along side surfaces of the plurality of channel layers on portions of the active pattern on both sides of the gate structure, and a second epitaxial layer on the first epitaxial layer, the second epitaxial layer defining a trench therein; an interlayer insulating layer on the device isolation layer and on the source/drain patterns; and contact structures penetrating the interlayer insulating layer, the contact structures connected to the source/drain patterns, respectively, and the contact structures being between the blocking insulating layers.

Some example embodiments of the inventive concepts also provide a method of manufacturing a semiconductor device that includes preparing a plurality of channel layers stacked on a substrate, a gate structure surrounding the plurality of channel layers, source/drain patterns connected to side surfaces of the plurality of channel layers, respectively, and a semiconductor structure including an interlayer insulating layer covering the source/drain patterns, wherein the gate structure includes a gate electrode surrounding the plurality of channel layers, gate spacers on both side surfaces of the gate electrode, respectively, and a gate capping layer on the gate electrode and the gate spacers, and the gate capping layer having a material different from a material of the gate spacers; forming contact holes in the interlayer insulating layer, the contact holes extending to the source/drain patterns; depositing a blocking insulating layer on an internal surface of the gate structure and in the contact holes using an atomic deposition process using remote plasma, wherein the blocking insulating layer is deposited as including a portion on the gate capping layer having a thickness greater than a thickness of another portion of the blocking insulating layer; forming trenches in the source/drain patterns using the blocking insulating layer as a mask; and forming contact structures filling the trenches in the contact hole.

### BRIEF DESCRIPTION OF DRAWINGS

The above and other aspects, features, and advantages of example embodiments will be more clearly understood from the following detailed description, taken in combination with the accompanying drawings, in which:

FIG. 1 is a plan diagram illustrating a semiconductor device according to some example embodiments of the inventive concepts;

FIG. 2 is a cross-sectional diagram illustrating a semiconductor device taken along line I-I′ in FIG. 1;

FIGS. 3A and 3B are cross-sectional diagrams illustrating a semiconductor device taken along lines II1-II1′ and II2-II2′ in FIG. 1;

FIG. 4 is a graph illustrating a deposition thickness depending on a base material to describe a selective deposition process for a blocking insulating layer according to some example embodiments;

FIG. 5 is a cross-sectional diagram illustrating a semiconductor device according to some example embodiments of the inventive concepts;

FIGS. 6A and 6B are cross-sectional diagrams illustrating a semiconductor device according to some example embodiments of the inventive concepts;

FIGS. 7A, 7B, 7C and 7D are cross-sectional diagrams illustrating a portion of processes (forming a fin structure and a dummy gate structure) among processes of a method of manufacturing a semiconductor device according to some example embodiments of the inventive concepts;

FIGS. 8A, 8B, 8C, 8D and 8E are cross-sectional diagrams illustrating another portion of processes (forming a source/drain pattern) among processes of a method of manufacturing a semiconductor device according to some example embodiments of the inventive concepts;

FIGS. 9A, 9B and 9C are cross-sectional diagrams illustrating another portion of processes (forming a contact structure) among processes of a method of manufacturing a semiconductor device according to some example embodiments of the inventive concepts; and

FIGS. 10A, 10B and 10C are cross-sectional diagrams illustrating processes of a method of manufacturing a semiconductor device according to some example embodiments of the inventive concepts.

### DETAILED DESCRIPTION

Hereinafter, example embodiments will be described as follows with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

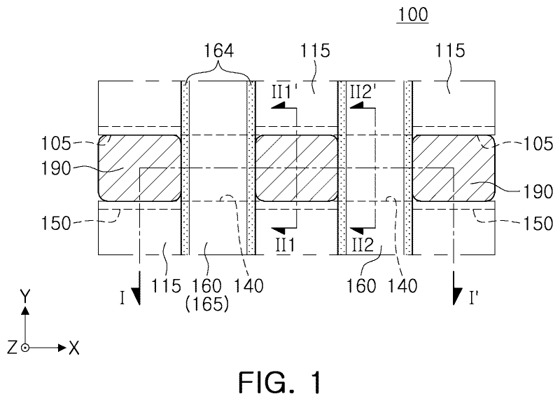

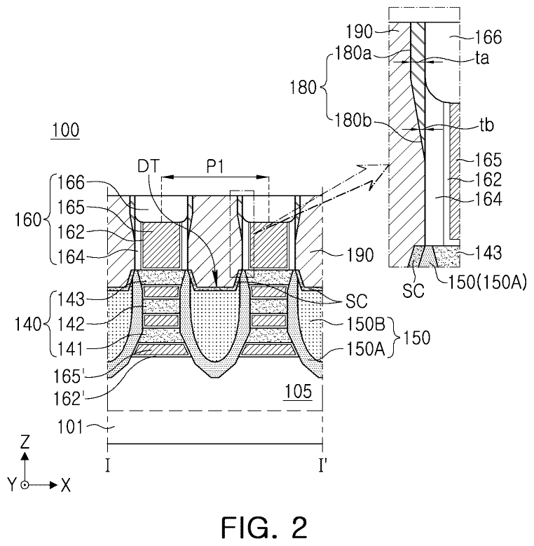

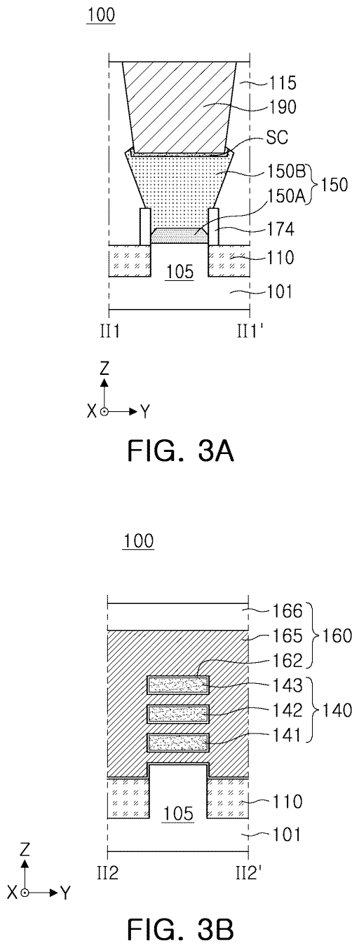

FIG. 1 is a plan diagram illustrating a semiconductor device according to some example embodiments. FIG. 2 is a cross-sectional diagram illustrating a semiconductor device taken along line I-I′ in FIG. 1. FIGS. 3A and 3B are cross-sectional diagram illustrating a semiconductor device taken along lines II1-II1′ and II2-II2′ in FIG. 1.

Referring to FIGS. 1, 2, 3A and 3B, a semiconductor device 100 according to the some example embodiments may include a substrate 101, a device protruding from the substrate 101 and extending in the first direction (e.g., X-direction), a plurality of channel layers 141, 142, and 143 disposed on the active pattern 105, a gate structure 160 crossing the active pattern 105 and extending in the second direction (e.g., Y-direction), and source/drain patterns 150 disposed on both sides of the gate structure 160 and in contact with both side surfaces of the plurality of channel layers 141, 142, and 143. The plurality of channel layers 141, 142, and 143 may be spaced apart from each other in a direction perpendicular to an upper surface of the substrate 101 (e.g., Z-direction) on the active pattern 105.

The semiconductor device 100 may further include blocking insulating layers 180 disposed on both side surfaces of the gate structure 160, and a contact structure 190 connected to the source/drain patterns 150 between the blocking insulating layers 180. Each of the blocking insulating layers 180 employed in some example embodiments may have an irregular thickness along both side surfaces of the gate structure 160.

As illustrated in FIG. 2, each of the blocking insulating layers 180 may have an upper region 180a having a first thickness ta and a lower region 180b having a second thickness tb smaller than the first thickness ta. The thickness conditions of the blocking insulating layer 180 may stably maintain a target critical dimension (CD) of the final contact structure 190, and may also improve electrical properties (improving contact resistance and reducing parasitic capacitance) of the semiconductor device 100. A detailed description thereof will be provided later.

In some example embodiments, the active pattern 105 may extend in the first direction (e.g., X-direction) and may have a protruding fin-type structure, as described above. For example, the substrate 101 may be a semiconductor substrate such as a silicon substrate or a germanium substrate, or a silicon-on-insulator (SOI) substrate.

Referring to FIGS. 3A and 3B, the device isolation layer 110 may define the active pattern 105. The device isolation layer 110 may be disposed on the substrate 101 to cover a side surface of the active pattern 105 of the substrate 101. The device isolation layer 110 may be formed such that an upper region of the active pattern 105 may be exposed. In some example embodiments, the device isolation layer 110 may have a curved upper surface having a level increasing toward the active pattern 105. For example, the device isolation layer 110 may include an oxide film, a nitride film, or a combination thereof. In some example embodiments, the device isolation layer 110 may be formed by a shallow trench isolation (STI) process. In some example embodiments, the device isolation layer 110 may further include a region extending deeper below an upper surface of the substrate 101. The regions extending deeper may also be referred to as deep trench isolation (DTI).

Referring to FIGS. 2 and 3B along with FIG. 1, an upper surface of the active pattern 105 may protrude from an upper surface of the device isolation layer 110 as described above. The channel structure 140 employed in some example embodiments may include three channel layers 141, 142, and 143 spaced apart from the upper surface of the active pattern 105 in a direction perpendicular to an upper surface of the substrate 101 (e.g., Z-direction). However, some example embodiments thereof are not limited thereto, and the number of the channel layers included in the channel structure 140 may be different (e.g., 4).

As illustrated in FIG. 2, the gate structure 160 may include a gate electrode 165 extending in the second direction (e.g., Y-direction) and surrounding the plurality of channel layers 141, 142, and 143, a gate insulating layer 162 disposed between the gate electrode 165 and the plurality of channel layers 141, 142, and 143, gate spacers 164 disposed on side surfaces of the gate electrode 162, and a gate capping layer 166 disposed on the gate electrode 165.

The gate insulating layer 162 may be disposed between the active pattern 105 and the gate electrode 165 and between the plurality of channel layers 141, 142, and 143 and the gate electrode 165, as illustrated in FIG. 2. The gate insulating layer 162 may be formed to surround the plurality of channel layers 141, 142, and 143 in the second direction (e.g., Y-direction), and may extend from an upper surface of the active pattern 105 to an upper surface of the device isolation layer 110 (see FIG. 3B). For example, the gate insulating layer 162 may include oxide, nitride, or a high-κ material. The high-κ material may refer to a dielectric material having a dielectric constant higher than that of silicon oxide (SiO₂). The high-κ material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrode 165 may be disposed by filling a space between the plurality of channel layers 141, 142, and 143 in an upper portion of the active pattern 105 and extending in the second direction from an upper portion of the third channel layer 143, which is an uppermost layer. The gate electrode 165 may be isolated from the plurality of channel layers 141, 142, and 143 by the gate insulating layer 162. The gate electrode 165 may include a conductive material, for example, a metal nitride such as titanium nitride film (TiN), tantalum nitride film (TaN), or tungsten nitride film (WN), and/or a metal material such as aluminum (Al), tungsten (W), or molybdenum (Mo) or a semiconductor material such as doped polysilicon. In some example embodiments, the gate electrode 165 may include two or more multilayers.

The gate spacers 164 may be disposed on both side surfaces of the gate electrode 165. The gate spacers 164 may insulate the source/drain patterns 150 and the gate electrodes 165. In some example embodiments, the gate spacers 164 may include a multilayer structure. For example, the gate spacers 164 may include a low-K film such as oxide and oxynitride. In some example embodiments, the gate spacers 164 may include a material different from a material of the gate capping layer 166. When the gate spacers 164 are a multilayer structure, at least an outermost layer of the multilayer structure may include a material different from a material of the gate capping layer 166.

For example, the gate capping layer 166 may include silicon nitride (SiN), and the gate spacers 164 may include silicon oxide (SiO₂), silicon carbonitride (SiCN), silicon oxynitride (SiON), silicon oxycarbonitride (SiOCN), silicon boron nitride (SiBN), silicon oxyboron nitride (SiOBN), and silicon oxycarbide (SiOC).

As described above, the blocking insulating layers 180 employed in the some example embodiments include upper and lower regions 180a and 180b having different thicknesses, and the upper and lower regions 180a and 180b may be distinguished by the gate capping layer 166 and the gate spacers 164 formed of different materials. As illustrated in FIG. 2, the upper region 180a may be disposed on both side surfaces of the gate capping layer 166 and may have a relatively large first thickness ta, and the lower region 180b may be disposed on a side surface of the gate spacers 164 and may have a relatively small second thickness tb. For example, the first thickness ta of the upper region 180a may range from 5 nm to 15 nm, and the second thickness tb of the lower region 180b may be 5 nm or less.

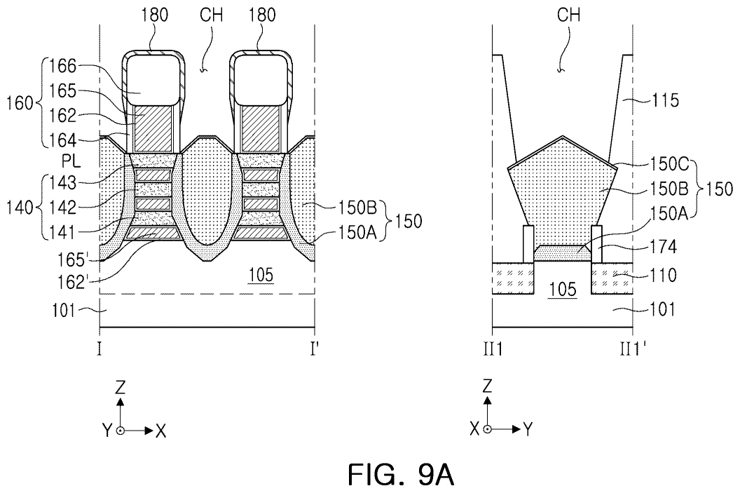

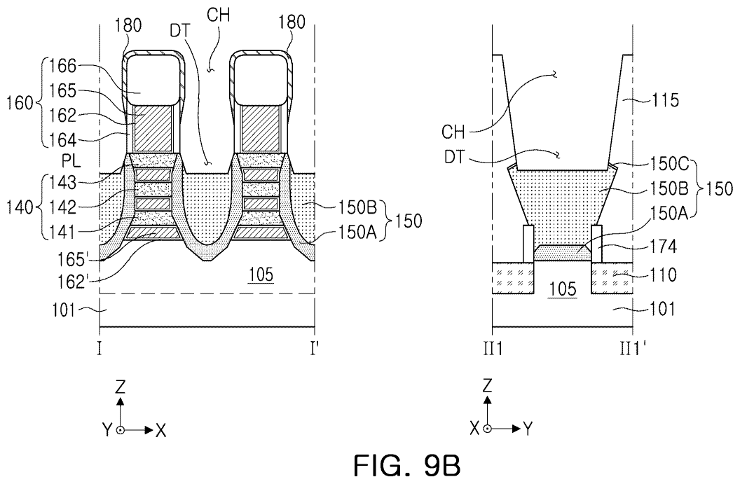

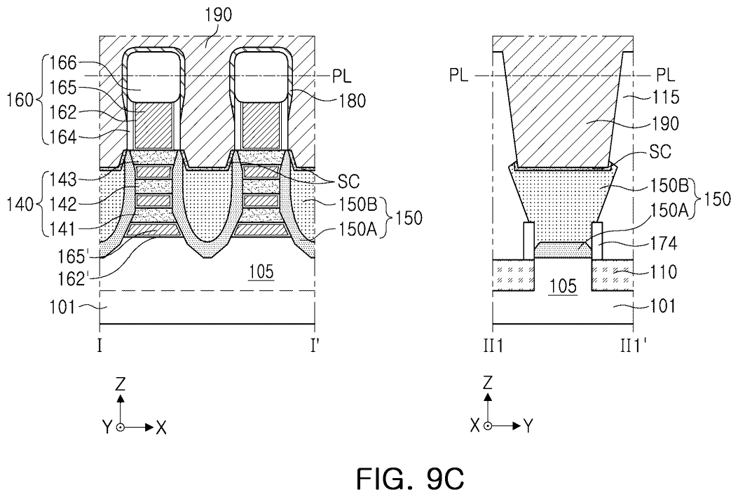

The upper region 180a of the blocking insulating layer 180 may be disposed to cover the gate structure 160 after the contact hole (“CH” in FIG. 9A) is formed and before the trench DT is formed in the source/drain pattern 150 (see FIG. 9A). In a process of forming a trench (see FIG. 9B), the upper region 180a of the blocking insulating layer 180 may cover the gate capping layer 166 with a sufficient thickness, thereby limiting and/or preventing loss of the gate structure 160. As described above, the upper region 180a of the blocking insulating layer 180 may limit and/or prevent a height of the gate structure 160 from being lowered or a structure (width or height) of the contact hole from being changed in the process of forming a trench.

The lower region 180b of the blocking insulating layer 180 employed in some example embodiments may have a relatively small second thickness tb, or may not be partially formed in a region adjacent to a lower end of the gate structure 160 as in some example embodiments.

Differently from the upper region 180a, the lower region 180b may be formed with a thin or relatively smaller thickness or may not be partially provided on the surface of the low-dielectric gate spacer 164 as described above, and an increase in parasitic capacitance due to residual blocking insulating layer may be effectively suppressed.

A thickness condition of the blocking insulating layer 180 according to the some example embodiments may be implemented by a process in which selective deposition may be performed depending on a material of the base (that is, a deposition surface) (see FIG. 9A). For example, the blocking insulating layer 180 may be formed using atomic layer deposition using remote plasma. For example, the blocking insulating layers 180 may include silicon nitride (SiN).

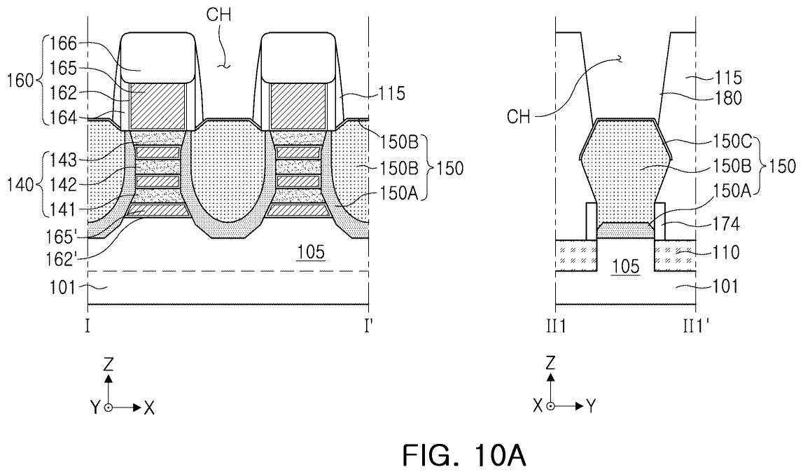

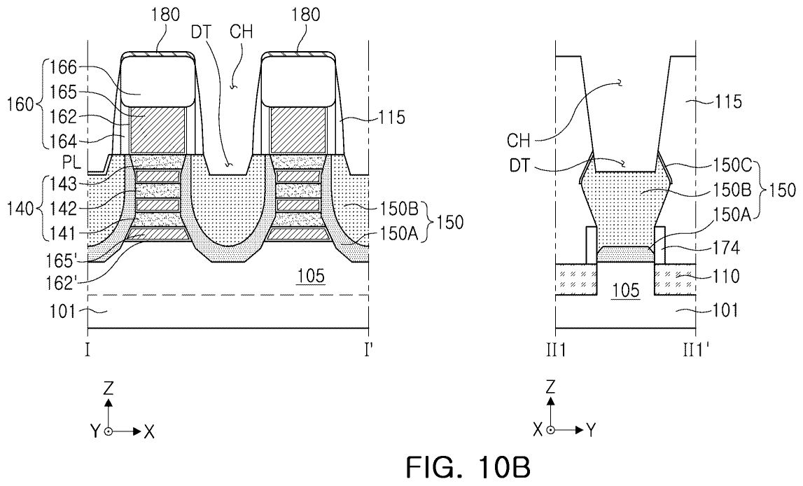

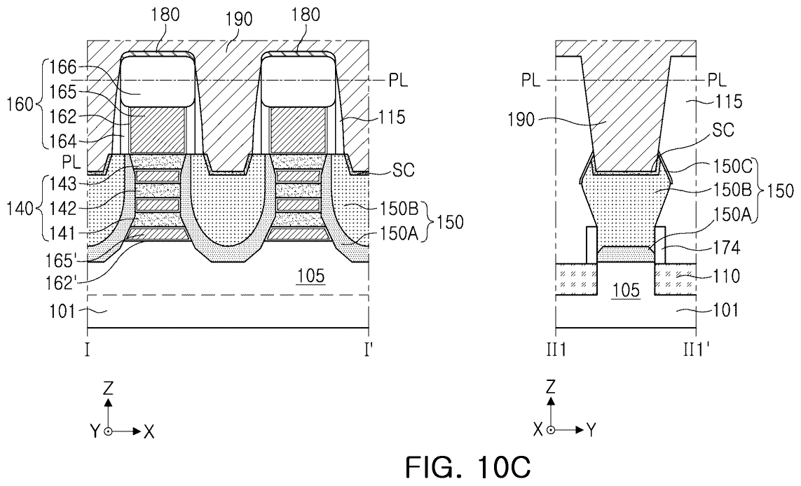

For example, the blocking insulating layer 180 may be grown on a surface of the gate capping layer 166 with a sufficient first thickness ta and on a surface of the gate spacer 164 with a relatively small second thickness tb using a difference in incubation time of the blocking insulating layer 180 depending on a base material. Also, since the growth of the blocking insulating layer 180 is suppressed on a bottom surface of the contact hole (see FIGS. 9A and 10B), an anisotropic etching process for the blocking insulating layer 180 to open the source/drain pattern 150 may not be performed before forming a trench (see FIGS. 9B and 10B). For example, the blocking insulating layer 180 may be barely formed (e.g., 1 nm or less) on the device isolation layer 110 exposed to a bottom surface of the contact structure 190 and the interlayer insulating layer 115 provided as a portion of sidewalls (sidewalls in the second direction) of the contact structure 1900 (see FIG. 3A).

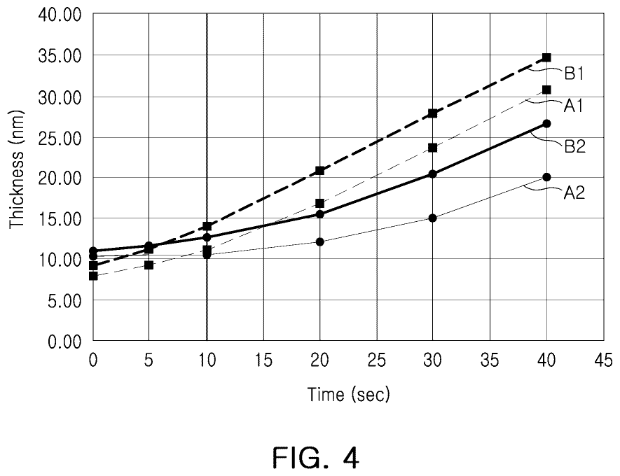

FIG. 4 is a graph illustrating a deposition thickness depending on a base material to describe a selective deposition process for a blocking insulating layer employed in some example embodiments.

In FIG. 4, the results of depositing a blocking insulating layer of silicon nitride (SiN) on different base materials simultaneously through an ALD process using remote plasma are illustrated. Here, the bases of other materials may be silicon nitride (SiN) (“A1” and “B1” marked by dotted lines) and silicon oxide (SiO₂) (“A2” and “B2” marked by solid lines), A1 and A2 may be the results of performing the ALD process in 3 cycles, and B1 and B2 represent the results of performing the ALD process in 5 cycles. A silicon nitride film may require a longer incubation time when formed on a silicon oxide base than when deposited on a silicon nitride base. Using this delayed deposition, a blocking insulating layer of silicon nitride may be selectively deposited on the silicon nitride base while barely growing a blocking insulating layer of silicon nitride on the silicon oxide base.

First, referring to the 3-cycle ALD process A1 and A2, when simultaneously depositing a blocking insulating layer of silicon nitride on a base A1 which is silicon nitride, and a base A2 which is silicon oxide, the blocking insulating layer may be deposited at different thicknesses due to differences in incubation time depending on the base material.

For example, a change in film thickness (start of deposition) of the blocking insulating layer of silicon nitride on the base A2 of silicon oxide may be observed after an incubation time of about 10 minutes, whereas on the base A1 of silicon nitride a change in a thickness is from 8 nm to 11 nm, and the blocking insulating layer may be deposited to 3 nm.

Similarly, referring to the 5-cycle ALD process B1 and B2, the blocking insulating layer of silicon nitride on the base B2 of silicon oxide may begin to be deposited after an incubation time of about 5 minutes, such that a film of a different thickness may be deposited depending on the base material.

Using this principle, the blocking insulating layer 180 employed in some example embodiments may be selectively deposited on the gate capping layer 166 which may be silicon nitride, while suppressing the growth of the interlayer insulating layer 115 and the device isolation layer 110 which may be silicon oxide. Also, since the gate spacers 164 also include a low dielectric material which may be the same as or similar to silicon oxide, the blocking insulating layer 180 (that is, lower region 180b) may be deposited on the gate spacers 164 with a thickness smaller than a thickness of the upper region 180a deposited on the gate capping layer 166.

As illustrated in FIG. 2, the lower region 180b of the blocking insulating layer 180 may have a thickness decreasing downwardly. In some example embodiments, the blocking insulating layer 180 may not be grown on at least a portion of a region of a side surface of the gate spacers 164 (particularly, the region adjacent to a lower end thereof).

Referring to FIGS. 1 and 2, the channel structure 140 and the active pattern 105 disposed on both sides of the gate structure 160 may be partially removed, thereby forming a recess for the source/drain patterns 150. Through the recess, side surfaces of the plurality of channel layers 141, 142, and 143 may be exposed, and the source/drain patterns 150 may be in contact with both side surfaces of each of the plurality of channel layers 141, 142, and 143 in the first direction (e.g., X-direction).

Referring to FIG. 2, a width of each of the first to third channel layers 141, 142, and 143 in the first direction (e.g., X-direction) may be equal to or similar (e.g., relatively smaller) to a width of the active pattern 105. Also, a width of each of the first to third channel layers 141, 142, and 143 in the first direction (e.g., X-direction) may be the same as or similar to a width of the gate structure 160. In some example embodiments, the widths of first to third channel layers 141, 142, and 143 may be slightly different from each other.

The first to third channel layers 141, 142, and 143 may include a semiconductor material which may provide a channel region. For example, the first to third channel layers 141, 142, and 143 may be a semiconductor pattern such as silicon (Si), silicon germanium (SiGe), or germanium (Ge). In some example embodiments, the first to third channel layers 141, 142, and 143 may be formed of the same material (e.g., silicon) as a material of the substrate 101. In some example embodiments, a region adjacent to the source/drain pattern 150 of the first to third channel layers 141, 142, and 143 may include an impurity region.

In some example embodiments, as illustrated in FIG. 2, the source/drain patterns 150 may include a first epitaxial layer 150A disposed along side surfaces of the plurality of channel layers 141, 142, and 143 on a portion of a region of the active pattern 105 on both sides of the gate structure 160, and a second epitaxial layer 150B disposed on the first epitaxial layer 150A and having a trench DT. The first epitaxial layer 150A and the second epitaxial layer 150B may have different compositions.

The semiconductor device 100 according to some example embodiments may be a P-type MOSFET. Each of the source/drain patterns 150 may include an epitaxial layer doped with P-type impurities. For example, the P-type impurity may include at least one of B, Al, Ga, and In. Each of the first and second epitaxial layers 150A and 150B may include silicon germanium (SiGe), and a first concentration of germanium (Ge) of the first epitaxial layer 150A may be lower than than a second concentration of germanium (Ge) of the second epitaxial layer 150B. For example, the first concentration of the first epitaxial layer 150A may be 5 atomic % to 20 atomic %, and the second concentration of the second epitaxial layer 150B may be 30 atomic % to 70 atomic %. The semiconductor device 100 according to some example embodiments may be an N-type MOSFET. Each of the source/drain patterns 150 may include an epitaxial layer doped with N-type impurities. For example, the N-type impurity may include at least one of P, As Sb, and Bi. Each of the first and second epitaxial layers 150A and 150B may include silicon epitaxial layers having different impurities or different concentrations of impurities.

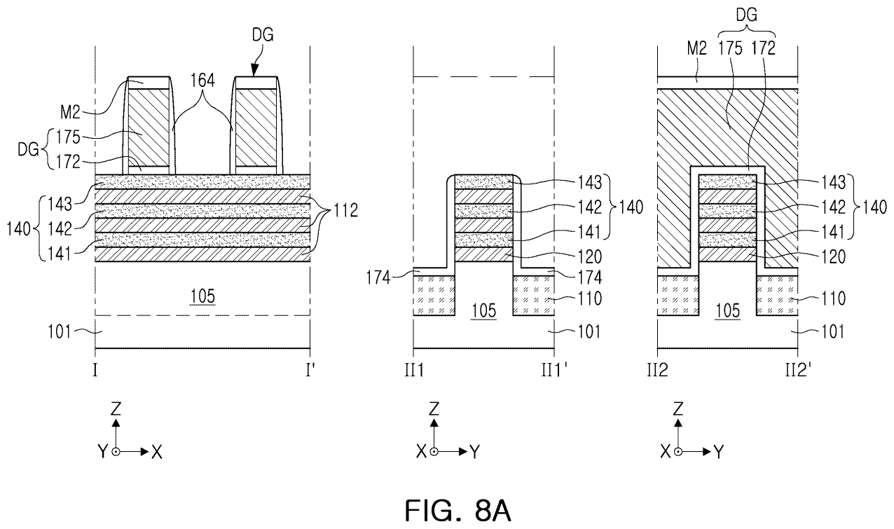

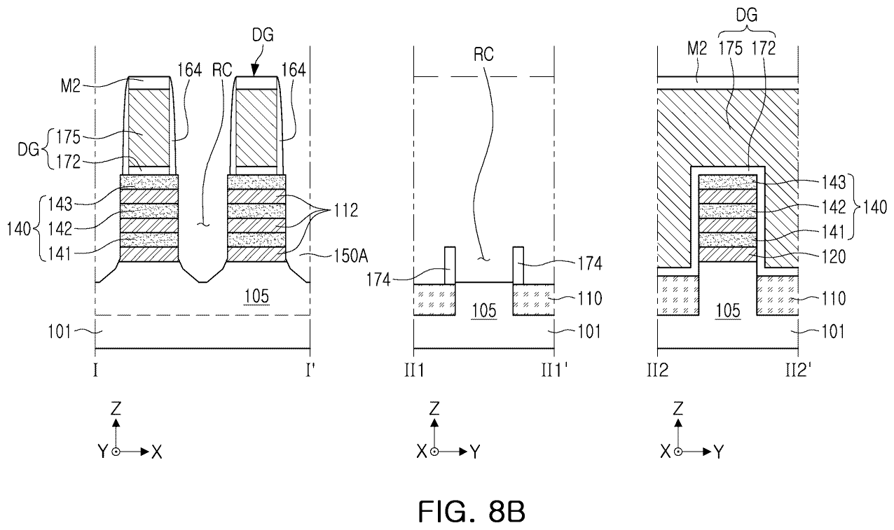

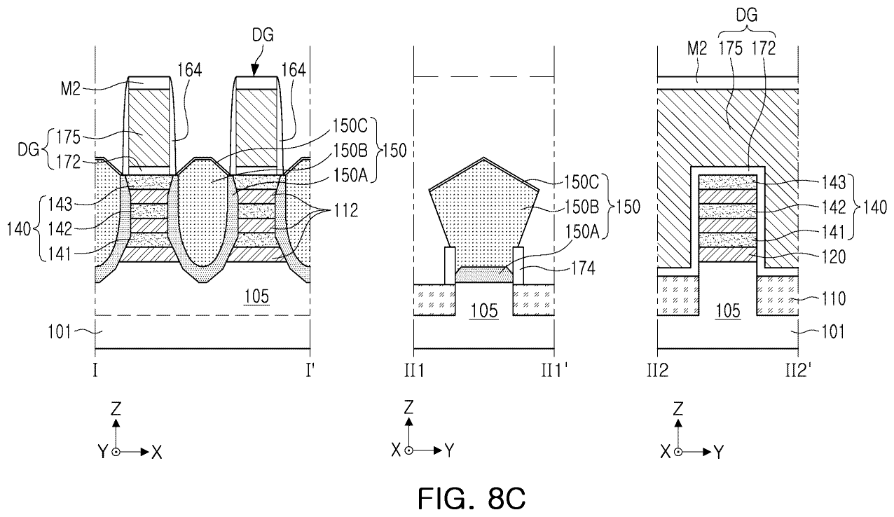

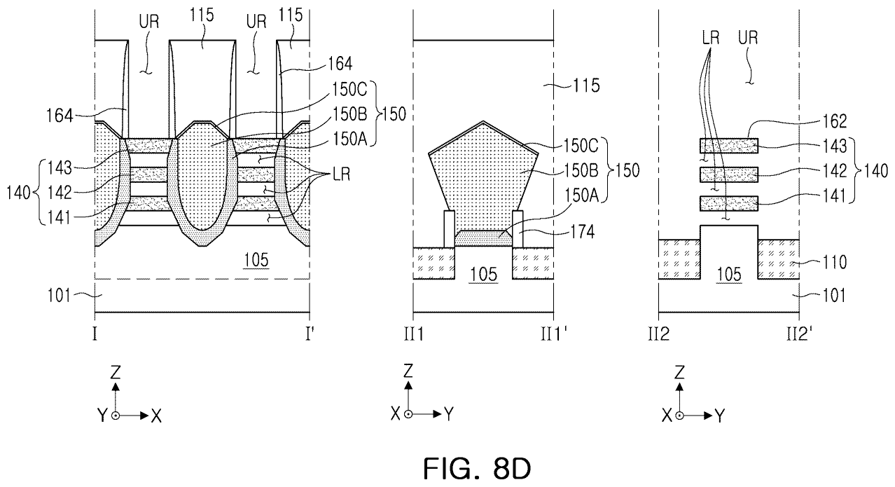

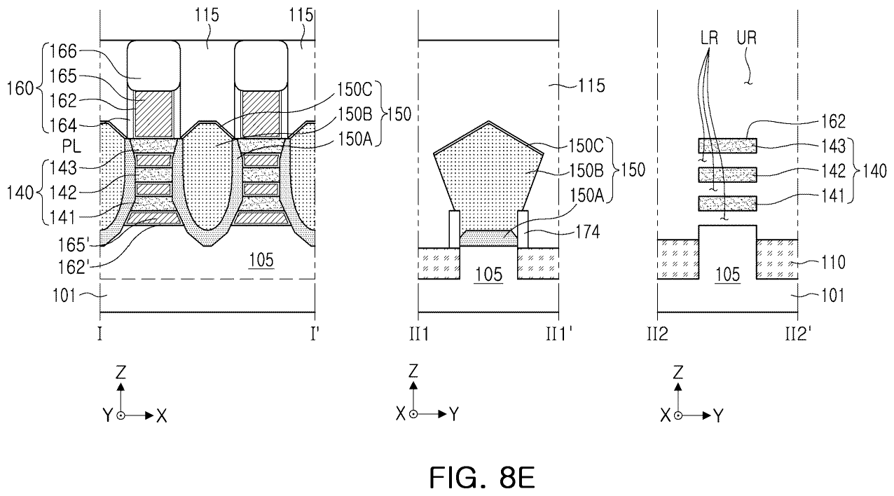

In some example embodiments, the source/drain patterns 150 may include a third epitaxial layer (see 150C in FIG. 8D) on the second epitaxial layer 150B as a cap layer. As in some example embodiments, the third epitaxial layer may be metallized with a metal-semiconductor compound layer SC, and residue thereof may barely remain in the final structure. For example, the metal-semiconductor compound layer 180 may include TiGe, or TiSiGe.

The interlayer insulating layer 115 may be disposed on the device isolation layer 110 and may cover the source/drain patterns 150 and the gate structure 160 (see FIG. 3A). For example, the interlayer insulating layer 115 may include at least one of oxide, nitride, and oxynitride, and may include a low-κ material.

Referring to FIG. 1, FIGS. 2 and 3A, the semiconductor device 100 according to some example embodiments may include a contact structure 190 penetrating an interlayer insulating layer 115, and a metal-semiconductor compound layer SC between the source/drain patterns 150 and the contact structure 190. An electrical signal may be applied to the source/drain patterns 150 through the contact structure 190, and contact resistance may be improved through the metal-semiconductor compound layer SC.

The contact structure 190 may be formed such that the trench DT of the second epitaxial layer 150B may be filled. The contact structure 190 may have a bottom surface lower than the third channel layer 143, which is an uppermost layer, in a direction perpendicular to an upper surface of the substrate 101. Accordingly, the contact structure 190 may extend into the trench DT and may increase a contact area with the source/drain patterns 150, such that contact resistance may be significantly improved.

In some example embodiments, the contact structure 190 may have a structure in which a width of a lower portion may be narrower than a width of an upper portion. For example, the contact structure 190 may include a metal material such as aluminum (Al), tungsten (W), or molybdenum (Mo). The contact structure 190 may further include a barrier material film, such as titanium nitride film (TiN), tantalum nitride film (TaN), or tungsten nitride film (WN), surrounding a metal material.

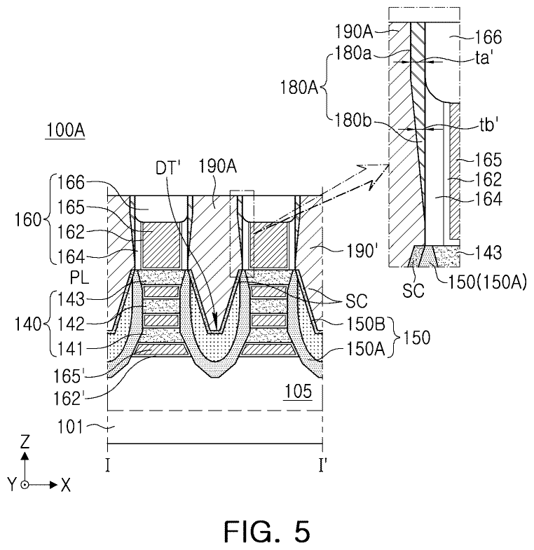

FIG. 5 is a cross-sectional diagram illustrating a semiconductor device according to an some example embodiments, viewed from the side.

Referring to FIG. 5, a semiconductor device 100A according to the some example embodiments may be configured the same as or similar to the semiconductor device 100 illustrated in FIGS. 1 to 3B other than the configuration in which the blocking insulating layer 180A may be formed to cover a side surface of the gate spacers 164 up to a lower end thereof and the configuration in which a trench DT′ of the source/drain pattern 150 is formed deeper. Also, unless otherwise indicated, the components of some example embodiments referring to FIG. 5 may be understood with reference to the descriptions of the same or similar components of the semiconductor device 100 illustrated in FIGS. 1 to 3B.

The blocking insulating layer 180A employed in some example embodiments may be disposed on almost the entire side surface of the gate structure 160. For example, the blocking insulating layer 180A may include an upper region 180a having a first thickness and a lower region 180b having a second thickness smaller than the first thickness, similarly to some example embodiments described referring to FIGS. 1 to 3B. However, the lower region 180b may be formed to cover a side surface of the gate spacers 164 up to a lower end thereof, and may have a thickness gradually decreasing toward the lower end. Differently from the thickness of the blocking insulating layer 180a, a width of the lower end of the gate structure 160 may be relatively larger than a width of an upper end, such that changes in CD of the contact structure due to the blocking insulating layer 180A according to some example embodiments may be greatly alleviated.

The trench DT′ of the source/drain pattern 150 employed in some example embodiments may be formed deeper than some example embodiments described referring to FIGS. 1 to 3B. As illustrated in FIG. 5, the source/drain patterns 150 may include a first epitaxial layer 150A disposed along side surfaces of the plurality of channel layers 141, 142, and 143 on a portion of a region of the active pattern 105 on both sides of the gate structure 160, and a second epitaxial layer 150B disposed on the first epitaxial layer 150A and having a trench DT′. A bottom surface of the trench DT′ may have a bottom level overlapping at least a portion of the lowest first channel layer 141. Accordingly, the contact structure 190 may extend into the trench DT′ and may further increase a contact area with the source/drain patterns 150.

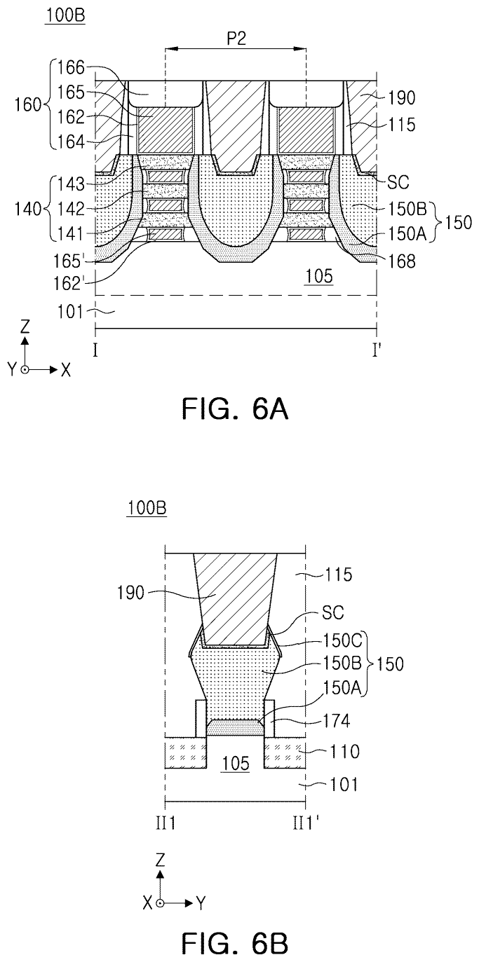

FIGS. 6A and 6B are cross-sectional diagrams illustrating a semiconductor device according to some example embodiments.

Referring to FIGS. 6A and 6B, the semiconductor device 100B according to some example embodiments may be configured the same as or similar to the semiconductor device 100 illustrated in FIGS. 1 to 3B, other than the configuration in which the semiconductor device may have a width and pitch P2 greater than a width and a pitch P1 of the gate structure according to some example embodiments referring to FIG. 2, the configuration in which the interlayer insulating layer 115 may remain in a region between the contact structure 190 and the gate structure 160, and the blocking insulating layer may not remain, and the configuration in which internal spacers 168 may be disposed between the plurality of channel layers 141, 142, and 143. Also, unless otherwise indicated, the components of some example embodiments referring to FIGS. 6A and 6B may be understood with reference to descriptions of the same or similar components of the semiconductor device 100 illustrated in FIGS. 1 to 3B.

The gate structure 160 employed in some example embodiments may have a width and a pitch P2 greater than a width and a pitch P1 of the gate structure in some example embodiments described with respect to FIGS. 1 to 3B. In some example embodiments (see FIG. 2), side surfaces of the contact structure 190 in the first direction (e.g., X-direction) may be in contact with the blocking insulating layer 180 on a side surface of the gate structure 160, whereas in some example embodiments referring to FIGS. 6A and 6B, the interlayer insulating layer 115 may remain on a side surface of the gate structure 160. As such, when the pitch P2 of the gate structure 160 is large, the interlayer insulating layer 115 may remain on a side surface of the gate structure 160 even after forming the contact hole (see FIG. 10A), such that the blocking insulating layer 180 may be selectively deposited only on a surface of the gate capping layer 166, and may not be barely formed on the interlayer insulating layer 115. Accordingly, as illustrated in FIG. 6A, in the final structure, only the interlayer insulating layer 115 may remain without a blocking insulating layer on the side surfaces of the contact structure 190 in the first direction (e.g., X-direction).

In some example embodiments, the semiconductor device 100B may further include internal spacers 168 disposed on both side surfaces of the gate electrode 165 between the channel layers 141, 142, and 143. The gate electrode 165 may be spaced apart from the source/drain patterns 150 by the internal spacers 168 and may be electrically isolated in a lower portion of the third channel layer 143. The internal spacers 168 may have a curved side surface in contact with the gate electrode 165 toward the gate electrode 165, but in some example embodiments thereof is not limited thereto. For example, the internal spacers 168 may include oxide, nitride and oxynitride. In particular, the internal spacers 168 may be formed as a low-K film.

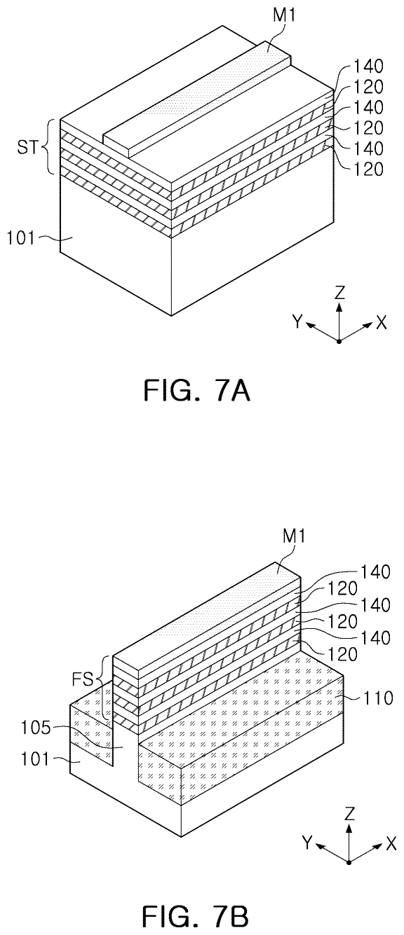

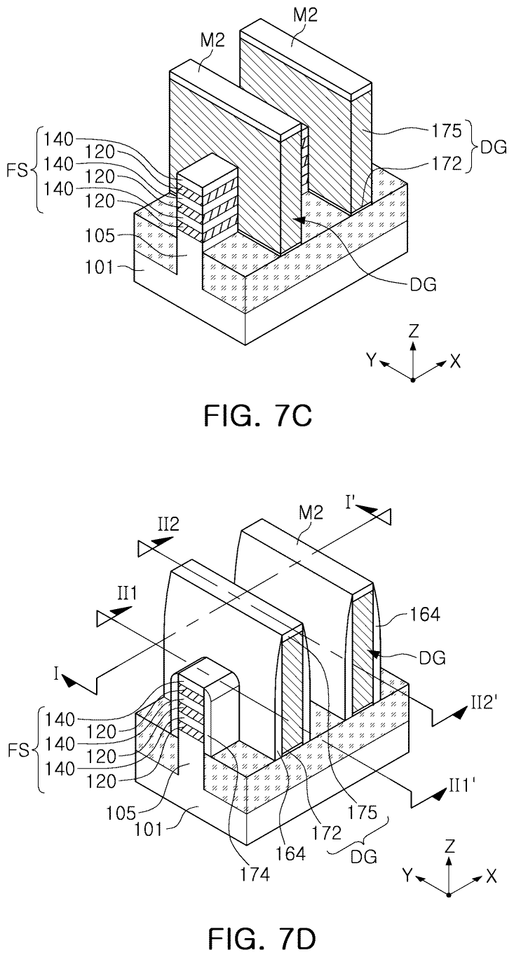

FIGS. 7A to 7D are cross-sectional diagrams illustrating a portion of processes (forming a fin structure and a dummy gate structure) among processes of a method of manufacturing a semiconductor device according to some example embodiments.

Referring to FIG. 7A, a semiconductor stack ST in which the first semiconductor layers 120 and the second semiconductor layers 140 may be alternately stacked may be formed on a substrate 101.

The first semiconductor layers 120 may be removed in a subsequent process and may be used as a sacrificial layer, and the second semiconductor layers 120 may be used as a channel layer. The first semiconductor layers 120 and the second semiconductor layers 140 may include a semiconductor material including at least one of silicon (Si), silicon germanium (SiGe), and germanium (Ge), and may include different semiconductor materials. The first semiconductor layers 120 may be formed of a material having relatively high etch selectivity with respect to the second semiconductor layers 140. The second semiconductor layers 140 may include impurities, but some example embodiments thereof are not limited thereto. In some example embodiments, the first semiconductor layers 120 may include silicon germanium (SiGe), and the second semiconductor layers 140 may include silicon (Si). The first semiconductor layers 120 and the second semiconductor layers 140 may be grown on the substrate 101 through an epitaxial growth process. Each of the first semiconductor layers 120 and the second semiconductor layers 140 may have a thickness ranging from approximately 2 nm to 100 nm.

Thereafter, referring to FIG. 7B, an active structure may be formed by removing a portion of the semiconductor stack ST and the substrate 101 using the first mask pattern M1 extending in the first direction (e.g., X-direction).

The active structure may include an active pattern 105 and a fin structure FS. The active pattern may include a structure protruding from an upper surface of the substrate 101 by removing a portion of the substrate 101, and the fin structure FS may include first semiconductor patterns 120 and second semiconductor patterns 140 alternately stacked on the active pattern 105. The active pattern 105 and the fin structure FS may be formed in the form of a line extending in one direction, for example, the first direction (e.g., X-direction). In the region in which a portion of the substrate 101 has been removed, an insulating material may be filled therein and may be etched back such that a portion of the active pattern 105 may protrude, thereby forming a device isolation layer 110. That is, an upper surface of device isolation layer 110 may be etched back lower than an upper surface of the active pattern 105.

Thereafter, referring to FIG. 7C, dummy gate structures DG extending in the second direction (e.g., Y-direction) to intersect a portion of a region of the active structure may be formed.

The dummy gate structures DG may be a sacrificial structure formed in the region in which the gate insulating layer 162 and the gate electrode 165 are disposed in an upper portion of the first to third channel layers 141, 142, and 143 illustrated in FIG. 2 through a subsequent process. The dummy gate structures DG may have a line shape intersecting the active structures and extending in the second direction (e.g., Y-direction), and may be spaced apart from each other in the first direction (e.g., X-direction). After forming the first and second sacrificial gate layers 172,175 stacked in order on the substrate 101 (in particular, the device isolation layer 110) on which the active structure is formed, by patterning the stack using the second mask pattern M2, the dummy gate structures DG may be formed.

The first and second sacrificial gate layers 172, 175 may be an insulating layer and a conductive layer, respectively, but some example embodiments thereof are not limited thereto, and the first and second sacrificial gate layers 172,175 may be integrated with each other. In some example embodiments, the first sacrificial gate layer 172 may include silicon oxide, and the second sacrificial gate layer 175 may include polysilicon. The second mask pattern M2 may include silicon oxide and/or silicon nitride.

Thereafter, referring to FIG. 7D, the gate spacers 164 on both side surfaces of the dummy gate structures DG and the fence spacers 174 on both side surfaces of the active structure may be formed.

A spacer material layer may be formed on the dummy gate structure DG and the active structure, anisotropic etching may be applied to form the gate spacers 164 on both side surfaces of the dummy gate structure DG, and the fence spacers 174 may be formed on both side surfaces of the active structure, that is, the active pattern 105 and both side surfaces of the fin structure FS. Both side surfaces formed with the gate spacers 164 may be side surfaces facing in the first direction (e.g., X-direction) of the dummy gate structures DG, and both side surfaces on which the fence spacers 174 are formed may be side surfaces opposing in the second direction (e.g., Y-direction) of the active structure. Also, the gate spacers 164 and the fence spacers 174 may be formed of the same material. The spacer material layer, that is, the gate spacers 164 and the fence spacers 174, may be formed of a low-K material and may include, for example, at least one of SiO, SiN, SiCN, SiOC, SiON, and SiOCN.

FIGS. 8A to 8E are cross-sectional diagrams illustrating another portion of processes (forming a source/drain pattern) among processes of a method of manufacturing a semiconductor device according to some example embodiments.

FIG. 8A illustrates a cross-section surface of the semiconductor structure in FIG. 7D taken along lines I-I′, and cross-sectional surfaces of the semiconductor structure in FIG. 7D taken along lines II1-II1′ and II2-II2′. Here, the sacrificial layers 120 may correspond to the first semiconductor pattern 120 illustrated in FIG. 7D, and the channel layers 141, 142, and 143 may correspond to the second semiconductor pattern 140 illustrated in FIG. 7A.

Thereafter, referring to FIG. 8B, a recess RC may be formed by removing partial regions of the fin structure FS disposed on both sides of the dummy gate structures DG.

The exposed sacrificial layers 120 and the channel layers 141, 142, and 143 may be removed using the second mask pattern M2 and the gate spacers 164 as a mask. Through this process, a length of channel layers 141, 142, and 143 in the first direction (e.g., X-direction) may be determined. In a lower portion of the dummy gate structures DG, the sacrificial layers 120 and the channel layers 141, 142, and 143 may be partially removed from a side surface such that both side surfaces along the first direction (e.g., X-direction) may be disposed in a lower portion of the dummy gate structures DG and the gate spacers 164. Also, after this process, the fence spacers 174 disposed on both side surfaces of the active structure may remain. In the process of removing the exposed portions of the sacrificial layers 120 and channel layers 141, 142, and 143, a portion of the fence spacers 174 may also be lost, and accordingly, a height of the fence spacers 174 may be determined.

Thereafter, referring to FIG. 8C, a first epitaxial layer 150A may be formed to form the source/drain patterns 150 in the recess RC disposed on both sides of the dummy gate structures DG, and a source/drain pattern 150 may be formed by growing the second epitaxial layer 150B and the third epitaxial layer 150C on the first epitaxial layer 150A.

The source/drain pattern 150 may include silicon or silicon germanium (SiGe). The first to third epitaxial layers 150A, 150B, and 150C may include epitaxial layers with different compositions. The first epitaxial layer 150A may be grown continuously from an upper surface region of the active pattern 105, which is a bottom surface of the recess region RC, and side surfaces of the channel layers 141, 142, and 143. In the process of growing the first epitaxial layer 150A, the first epitaxial layer 150A may be grown from an upper surface region of the active pattern 105 and side surfaces of plurality of channel layers 141, 142, and 143, portions grown from side surfaces of adjacent channel layers 141, 142, and 143 may be merged with each other, such that the first epitaxial layer 150A may be grown continuously along a sidewall of the recess RC. The second epitaxial layer 150B may be grown from the first epitaxial layer 150A using the SEG process. Also, the third epitaxial layer 150C may be grown as a cap layer on the second epitaxial layer 150B.

In the case of a P-type source/drain pattern, the first and second epitaxial layers 150A and 150B may include epitaxial layer doped with P-type impurities and may include silicon germanium (SiGe) having different compositions. For example, P-type impurities may include at least one of B, Al, Ga, and In. For example, a first concentration of germanium (Ge) of the first epitaxial layer 150A may be 5 atomic % to 20 atomic %, and a second concentration of germanium (Ge) of the second epitaxial layer 150B may be 30 atomic % to 70 atomic %. Also, the third epitaxial layer 150C may include germanium (Ge).

Thereafter, referring to FIG. 8D, the interlayer insulating layer 115 may be formed, and the sacrificial layers 120 and the dummy gate structures DG may be removed, thereby forming upper gap regions UR and lower gap regions LR.

The interlayer insulating layer 115 may be formed by forming an insulating film covering the dummy gate structures DG and the source/drain patterns 150 and performing a planarization process. The sacrificial layers 120 and the dummy gate structure DG may be selectively removed for the gate spacers 164, the interlayer insulating layer 115, and the channel layers 141, 142, and 143. First, the upper gap regions UR may be formed by removing the dummy gate structures DG along with the second mask pattern M2, and the lower gap regions LR may be formed by removing the sacrificial layers 120 exposed through the upper gap regions UR. For example, when the sacrificial layers 120 include silicon germanium (SiGe) and the channel structure 140 includes silicon (Si), the sacrificial layers 120 may be selectively removed by performing a wet etching process using peracetic acid as an etchant. During the removal process, the source/drain patterns 150 may be protected by the interlayer insulating layer 115.

Thereafter, referring to FIG. 8E, the gate structures 160 may be formed in the upper gap regions UR and the lower gap regions LR.

First, the gate insulating layer 162 may be formed to conformally cover internal surfaces of the upper gap regions UR and the lower gap regions LR. The gate electrodes 165 may be formed to completely bury the upper gap regions UR and the lower gap regions LR, and may be removed from the upper gap regions UR to a desired (and/or alternatively predetermined) depth. The gate capping layer 166 may be formed in the region from which gate electrodes 165 are removed from the upper gap regions UR. Through these processes, the gate structures 160 including the gate insulating layer 162, the gate electrode 165, the gate spacers 164, and the gate capping layer 166 may be formed.

FIGS. 9A to 9C are cross-sectional diagrams illustrating another portion of processes (forming a contact structure) among processes of a method of manufacturing a semiconductor device according to some example embodiments.

Referring to FIG. 9A, a contact hole CH may be formed in the interlayer insulating layer 115, and a blocking insulating layer 180 may be formed.

A contact hole CH for the contact structure 190 may be formed by partially removing the interlayer insulating layer 115 between the gate structures 160. In some example embodiments, a width of the contact hole CH in the first direction (e.g., X-direction) may be defined by a distance of the gate structure 160. The width of the contact hole CH in the second direction (e.g., Y-direction) may be similar to a width of the source/drain pattern 150. Accordingly, side surfaces of the source/drain pattern 150 may be opened through the contact hole CH.

Subsequently, the blocking insulating layer 180 may be selectively formed on the gate structures 160. The blocking insulating layer 180 may be provided as a structure to limit and/or prevent loss of the gate structure 160 during the process of forming a trench in the subsequent source/drain pattern 150. For example, the blocking insulating layers 180 may include silicon nitride (SiN).

Conventionally, the blocking insulating layer 180 may be conformally formed using an ALD process, but in the some example embodiments of the inventive concepts, the blocking insulating layer 180 may be formed by a process in which selective deposition may be performed depending on a material of a base (that is, deposition surface). For example, the blocking insulating layer 180 may be formed using an atomic deposition process using remote plasma. For example, using a difference in the incubation time of the blocking insulating layer 180 depending on the base material, the blocking insulating layer 180 may be grown with a sufficient first thickness ta on a surface of the gate capping layer 166, and may be grown with a relatively small second thickness tb on a surface of the gate spacer 164. Also, the blocking insulating layer 180 may be hardly grown on the interlayer insulating layer 115 and the device isolation layer 110.

For example, the gate capping layer 166 may include silicon nitride (SiN), and the gate spacers 164 may include at least one of silicon carbonitride (SiCN), silicon oxynitride (SiON), silicon oxycarbonitride (SiOCN), silicon boronitride (SiBN), silicon oxyboron nitride (SiOBN), and silicon oxycarbide (SiOC). Also, the interlayer insulating layer 115 and the device isolation layer 110 may be silicon oxide (SiO₂).

Thereafter, referring to FIG. 9B, a trench DT may be formed in the source/drain patterns 150.

For example, this process may be performed using an anisotropic etching process such as reactive ion etching. Thereafter, a trench DT may be formed in the source/drain pattern 150 by etching the open source/drain pattern 150. In some example embodiments, a depth of the trench DT may be formed to overlap at least a portion of the first channel layer 141, which is a lowermost layer. In this process of forming a trench DT, the second epitaxial layer 150B may be removed along with the third epitaxial layer 150C, thereby forming a trench DT. The trench DT may have a structure surrounded by a second epitaxial layer 150B on a plan view. As described above, in this process, the blocking insulating layer 180 may limit and/or prevent loss of the gate structure 160, especially the gate capping layer 166.

Thereafter, referring to FIG. 9C, a metal-semiconductor compound layer SC may be formed on a surface of the source/drain pattern 150, and a contact structure 190 connected to a surface of the source/drain pattern 150 may be formed in the contact hole CH and the trench DT

A metal-semiconductor compound layer SC may be formed on a surface of the source/drain pattern 150. Mainly, a metal-semiconductor compound layer SC may be formed by depositing a metal layer (e.g., Ti) on the exposed third epitaxial layer 150C and annealing the layer. The metal-semiconductor compound layer SC may be formed on an upper surface of the source/drain pattern 150, and also on both side surfaces in the second direction (e.g., Y-direction). For example, the metal-semiconductor compound layer SC may include TiGe, or TiSiGe. In this process, most of the third epitaxial layer 150C may be metalized and may not remain in the final structure. Also, a portion of the adjacent second epitaxial layer 150B may also be metallized. A conductive material for the contact structure 190 may be deposited, and may be planarized along a line marked by the dotted line PL. In this planarization process, the blocking insulating layer portion remaining on an upper surface of the gate structure 160 may also be removed.

The blocking insulating layers 180 may remain between side surfaces of the contact structure 190 in the first direction (e.g., X-direction) and the gate structure 160. The blocking insulating layers 180 remaining in this process may include upper and lower regions 180a and 180b (e.g., see FIG. 2) having different thicknesses, and the upper and lower regions 180a and 180b may be distinguished by the gate capping layer 166 and the gate spacers 164 formed of different materials.

As illustrated in FIG. 9C and for example in FIG. 2, the upper region 180a may be disposed on both side surfaces of the gate capping layer 166 and may have a relatively large first thickness ta, and the lower region 180b may be disposed on side surfaces of the gate spacers 164 and may have a relatively small second thickness tb. For example, the first thickness ta of the upper region 180a may range from 5 nm to 15 nm, and the second thickness tb of the lower region 180b may be 5 nm or less. This thickness condition of the blocking insulating layer 180 may stably maintain a target CD of the final contact structure 190, and may also improve electrical properties (improving contact resistance and reducing parasitic capacitance) of the semiconductor device 100.

FIGS. 10A to 10C are cross-sectional diagrams illustrating processes of a method of manufacturing a semiconductor device according to some example embodiments. The process according to some example embodiments may be understood as a process of manufacturing the semiconductor device 100B illustrated in FIGS. 6A and 6B, in which a pitch of the gate structure may be relatively large.

Referring to FIG. 10A, a contact hole CH may be formed in an interlayer insulating layer 115.

Similarly to the aforementioned process, a contact hole CH for the contact structure 190 may be formed by partially removing the interlayer insulating layer 115 between the gate structures 160. Accordingly, side surfaces of the source/drain pattern 150 may be opened through the contact hole CH. In some example embodiments, since a distance between the gate structures is relatively large, a width of the contact hole CH in the first direction (e.g., X-direction) may be relatively smaller than a distance of the gate structure 160. In some example embodiments, the interlayer insulating layer 115 may remain on opposing sidewalls of the gate structures 160.

Thereafter, referring to FIG. 10B, a trench DT may be formed in the source/drain patterns 150 and a blocking insulating layer 180 may be formed.

In this process, the blocking insulating layer 180 may be selectively formed on the gate structures 160 using an atomic deposition process using remote plasma. The blocking insulating layer 180 may be provided as a structure to limit and/or prevent loss of the gate structure 160 during the process of forming a trench in the subsequent source/drain pattern 150. For example, the blocking insulating layers 180 may include silicon nitride (SiN).

For example, the blocking insulating layer 180 may be formed to have a sufficient thickness on an upper surface of the gate capping layer 166, whereas the blocking insulating layer 180 may barely grow on the interlayer insulating layer 115 provided as a sidewall of a contact hole and the device isolation layer 110 exposed on a bottom surface of the contact hole. For example, the gate capping layer 166 may include silicon nitride (SiN), and the interlayer insulating layer 115 and the device isolation layer 110 may be silicon oxide (SiO₂).

For example, this process may be performed using an anisotropic etching process such as reactive ion etching. Thereafter, a trench DT may be formed in the source/drain pattern 150 by etching the open source/drain pattern 150. In this process of forming a trench DT, the second epitaxial layer 150B may be removed along with the third epitaxial layer 150C, thereby forming the trench DT. As described above, in this process, the blocking insulating layer 180 may limit and/or prevent loss of the gate structure 160, especially the gate capping layer 166.

Thereafter, referring to FIG. 10C, a metal-semiconductor compound layer SC may be formed on a surface of the source/drain pattern 150, and a contact structure 190 connected to a surface of the source/drain pattern 150 may be formed in the contact hole CH and the trench DT.

A metal-semiconductor compound layer SC may be formed on a surface of the source/drain pattern 150. Mainly, a metal-semiconductor compound layer SC may be formed by depositing a metal layer (e.g., Ti) on the exposed third epitaxial layer 150C and annealing the layer. The metal-semiconductor compound layer SC may be formed on an upper surface of the source/drain pattern 150, and also on both side surfaces in the second direction (e.g., Y-direction). For example, the metal-semiconductor compound layer SC may include TiGe, or TiSiGe.

Differently from the above-mentioned some example embodiments, the blocking insulating layers may not be present between side surfaces of the contact structure 190 in the first direction (e.g., X-direction) and the gate structure 160, and the blocking insulating layers 180 on the gate structure 160 may be removed in a planarization process for forming the contact structure 190. As such, in some example embodiments, the selectively deposited blocking insulating layer 180 may not remain in the final structure.

According to some example embodiments, by suppressing growth on a bottom surface of the contact hole and the lower region of the gate structure (particularly the gate spacer) and forming the blocking insulating layer to have a sufficient thickness on an upper region of the gate structure (particularly the gate capping layer), deterioration of electrical properties (e.g., increase in parasitic capacitance) due to changes in a critical dimension (CD) of the contact structure, damage and increase in the thickness of the gate spacer may be effectively limited and/or prevented.

While some example embodiments have been illustrated and described above, it will be apparent to those skilled in the art that modifications and variations may be made without departing from the scope of example embodiments as defined by the appended claims.

1. A semiconductor device, comprising:
a substrate;
an active pattern extending on the substrate in a first direction;
a plurality of channel layers stacked on the active pattern, the plurality of channel layers being spaced apart from each other in a direction perpendicular to an upper surface of the substrate;
a gate structure crossing the active pattern, the gate structure surrounding the plurality of channel layers and extending in a second direction that intersects the first direction;
blocking insulating layers on both side surfaces of the gate structure, respectively, each of the blocking insulating layers having an upper region having a first thickness and a lower region having a second thickness smaller than the first thickness;
source/drain patterns on portions of the active pattern on both sides of the gate structure, the source/drain patterns connecting side surfaces of the plurality of channel layers, and the source/drain patterns defining trenches therein, respectively;
contact structures on the source/drain patterns between the blocking insulating layers, the contact structures filling the trenches; and
a metal-semiconductor compound layer between the source/drain patterns and the contact structures.

2. The semiconductor device of claim 1, wherein the lower region of each of the blocking insulating layers has a portion having a width decreasing along the direction perpendicular to the upper surface of the substrate.

3. The semiconductor device of claim 1, wherein the lower region of each of the blocking insulating layers does not cover a region adjacent to lower ends of the both side surfaces of the gate structure.

4. The semiconductor device of claim 1, wherein the second thickness of the lower region of each of the blocking insulating layers is 5 nm or less.

5. The semiconductor device of claim 1, wherein the first thickness of the upper region of each of the blocking insulating layers is in a range of 5 to 15 nm.

6. The semiconductor device of claim 1,
wherein the gate structure includes:
a gate electrode crossing the active pattern, the gate electrode extending in the second direction and surrounding the plurality of channel layers;
a gate insulating film between the gate electrode and the plurality of channel layers;
gate spacers on both side surfaces of the gate electrode in the second direction, respectively; and
a gate capping layer on the gate electrode and the gate spacers, the gate capping layer having a material different from a material of the gate spacers.

7. The semiconductor device of claim 6, wherein the upper region of each of the blocking insulating layers is on both side surfaces of the gate capping layer, and the lower region of each of the blocking insulating layers is on side surfaces of the gate spacers.

8. The semiconductor device of claim 6,
wherein the gate capping layer includes silicon nitride (SiN), and
wherein the gate spacers include at least one of silicon oxide (SiO₂), silicon carbonitride (SiCN), silicon oxynitride (SiON), silicon oxycarbonitride (SiOCN), silicon boronitride (SiBN), silicon oxyboronitride (SiOBN), and silicon oxycarbide (SiOC).

9. The semiconductor device of claim 8, wherein the blocking insulating layers include silicon nitride (SiN).

10. The semiconductor device of claim 1, wherein the trenches have a portion overlapping a lowest channel layer among the plurality of channel layers in a direction horizontal to the upper surface of the substrate.

11. The semiconductor device of claim 1, further comprising:
a first epitaxial layer along the side surfaces of the plurality of channel layers on a portion of a region of the active pattern on the both sides of the gate structure, and a second epitaxial layer on the first epitaxial layer,
wherein the trenches are formed in the second epitaxial layer.

12. The semiconductor device of claim 11, wherein each of the first epitaxial layer and the second epitaxial layer includes silicon germanium (SiGe), and a first concentration of germanium (Ge) of the first epitaxial layer is lower than a second concentration of germanium (Ge) of the second epitaxial layer.

13. The semiconductor device of claim 12, wherein the first concentration is 5 atomic % to 20 atomic %, and the second concentration is 30 atomic % to 70 atomic %.

14. A semiconductor device, comprising:
a substrate;
an active pattern extending on the substrate in a first direction;
a plurality of channel layers stacked on the active pattern, the plurality of channel layers being spaced apart from each other in a direction perpendicular to an upper surface of the substrate;
a gate structure including
a gate electrode crossing the active pattern, the gate structure surrounding the plurality of channel layers and extending in a second direction that intersects the first direction,
gate spacers on both side surfaces of the gate electrode, respectively, and
a gate capping layer on the gate electrode and the gate spacers, the gate capping layer having a material different from a material of the gate spacers;
source/drain patterns along side surfaces of the plurality of channel layers, the source/drain patterns being on portions of the active pattern on both sides of the gate structure, and the source/drain patterns defining trenches therein, respectively;
blocking insulating layers including first portions on both side surfaces of the gate capping layer, respectively, and second portions extending from the first portions to side surfaces of the gate spacers, respectively, and each of the second portions having a thickness smaller than a thickness of each of the first portions; and
contact structures on the source/drain patterns between the blocking insulating layers, the contact structures filling the trenches.

15. The semiconductor device of claim 14, wherein each of the second portions has a portion having a width decreasing along the direction perpendicular to the upper surface of the substrate, and each of the second portions does not cover a region adjacent to a lower end of each of the both side surfaces of the gate structure.

16. The semiconductor device of claim 14, wherein the gate capping layer and the blocking insulating layers include silicon nitride (SiN).

17. The semiconductor device of claim 16, wherein the gate spacers include at least one of silicon oxide (SiO₂), silicon carbonitride (SiCN), silicon oxynitride (SiON), silicon oxycarbonitride (SiOCN), silicon boronitride (SiBN), silicon oxyboronitride (SiOBN), and silicon oxycarbide (SiOC).

18. A semiconductor device, comprising:
a substrate;
an active pattern extending on the substrate in a first direction;
a device isolation layer on the substrate and defining the active pattern;
a plurality of channel layers stacked on the active pattern, the plurality of channel layers being spaced apart from each other in a direction perpendicular to an upper surface of the substrate;
a gate structure crossing the active pattern, the gate structure surrounding the plurality of channel layers and extending in a second direction that intersects the first direction;
blocking insulating layers on both side surfaces of the gate structure, respectively, and each of the blocking insulating layers having an upper region having a first thickness and a lower region having a second thickness smaller than the first thickness;
source/drain patterns including a first epitaxial layer along side surfaces of the plurality of channel layers on portions of the active pattern on both sides of the gate structure, and a second epitaxial layer on the first epitaxial layer, the second epitaxial layer defining a trench therein;
an interlayer insulating layer on the device isolation layer and on the source/drain patterns; and
contact structures penetrating the interlayer insulating layer, the contact structures connected to the source/drain patterns, respectively, and the contact structures being between the blocking insulating layers.

19. The semiconductor device of claim 18, wherein each of the blocking insulating layers are not on an internal sidewall of the interlayer insulating layer through which the contact structures penetrate.

20. The semiconductor device of claim 18, wherein each of the blocking insulating layers are not between bottom surfaces of the contact structures and the device isolation layer.

21.-25. (canceled)
